(19) United States
(12) Patent Application Publication
(10) Pub. No.: US 2020/0133480 A1
(43) Pub. Date: Apr. 30, 2020

(54) PORTABLE COMMUNICATION DEVICE

(71) Applicant: MOTOROLA SOLUTIONS, INC., Chicago, IL (US)

(72) Inventors: Wey Chien HENG, Georgetown, Penang (MY); Chee Kit CHAN, Ipoh, Perak (MY); Peng Khoon CHEAH, Gelugor, Penang (MY); Sih Hau TAN, Puchong, Selangor (MY); Jody H. AKENS, Weston, FL (US)

(21) Appl. No.: 16/095,872

(22) PCT Filed: May 16, 2016
(86) PCT No.: PCT/MY2016/000026

§ 371 Date: Oct. 23, 2018

(51) Int. Cl. G06F 3/0488; H04M 1/02; G06F 3/041; G06F 3/044; G06F 3/0489; G06F 1/16; H03K 17/96

(52) U.S. Cl. CPC G06F 3/04886; H04M 1/0266; G06F 3/0414; H04M 2250/22; G06F 3/04897; G06F 1/1626; H03K 17/9622; G06F 3/044

(57) ABSTRACT

A portable communication device includes a translucent housing, a display positioned under the translucent housing, a capacitive touch sensing interface positioned under the translucent housing and adjacent the display, an activation button, and an electronic processor electrically coupled to the display, the capacitive touch sensing interface, and the activation button.

### BACKGROUND OF THE INVENTION

Portable communication devices such as, for example, two-way radios, land mobile radios, hand-held telephones and the like often include inbuilt displays for information presentation and device control. The inbuilt displays often include a display viewing opening and physical buttons. However, these arrangements may be bulky, provide extraneous or unnecessary information to the user at any given time, and suffer from accidental activation or de-activation of features.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is perspective view of a portable communication device in accordance with one embodiment.

FIG. 2 is a perspective, exploded view of the portable communication device of FIG. 1.

FIG. 3 is a perspective view of the portable communication device of FIG. 1, in a non-active mode.

FIG. 4 is a perspective view of the portable communication device of FIG. 1, in an active mode.

FIG. 5 is a partial, perspective view of a display and a capacitive touch sensing interface of the portable communication device of FIG. 1, illustrating a first menu option and two control symbols that are lit up.

FIG. 6 is a partial, perspective view of the display and capacitive touch sensing interface of FIG. 4, illustrating a second menu option and two control texts that are lit up.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION OF THE INVENTION

One embodiment provides a portable communication device includes a translucent housing, a display positioned under the translucent housing, a capacitive touch sensing interface positioned under the translucent housing and adjacent the display, an activation button, and an electronic processor electrically coupled to the display, the capacitive touch sensing interface, and the activation button.

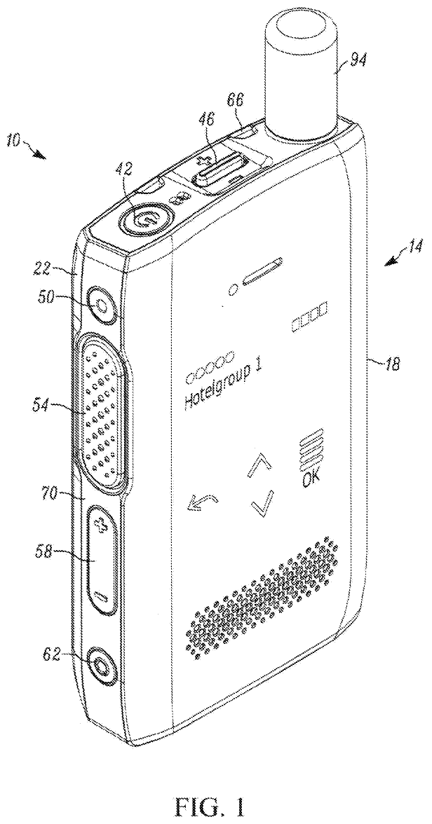

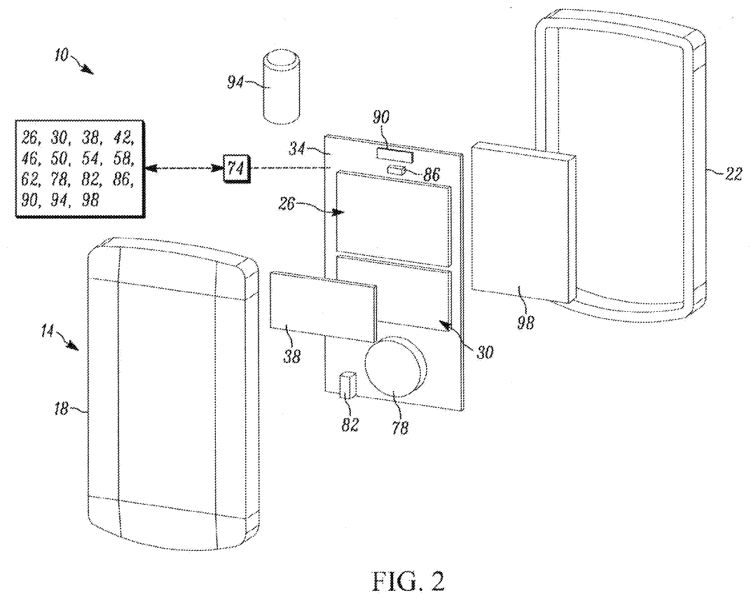

FIGS. 1 through 6 illustrate one example of a portable communication device 10. In the example illustrated, the portable communication device 10 includes a translucent housing 14. In some embodiments the translucent housing 14 defines an enclosure for the portable communication device 10. In some embodiments, the translucent housing 14 is made of plastic, although other embodiments include different materials. As illustrated in FIG. 2, the translucent housing 14 includes a front housing portion 18 and a back housing portion 22 that are coupled together (for example, with adhesive, a snap-fit, frictional engagement, or with one or more fasteners). In the illustrated embodiment, only the front housing portion 18 (or a portion thereof) is translucent, whereas the back housing portion 22 is opaque, although other embodiments include different arrangements. As described further herein, the front housing portion 18 (or at least a portion thereof) allows light from within the portable communication device 10 to be selectively transmitted through the front housing portion 18.

With reference to FIG. 2, the portable communication device 10 further includes a display 26 and a capacitive touch sensing interface 30 both positioned under the translucent housing 14. In the illustrated embodiment, the display 26 and the capacitive touch sensing interface 30 are both mounted to a printed circuit board 34, although in other embodiments one or both of the display 26 and the capacitive touch sensing interface 30 are mounted to a flexible printed circuit or other electronic component. As illustrated in FIG. 2, the display is mounted directly above, and adjacent to the capacitive touch sensing interface 30. The display 26 provides information to the user, for example in the form of text, symbols, or graphics, and in some embodiments provides menu options. The display 26 may be any of a number of different displays, including commercially available displays. The capacitive touch sensing interface 30 may be any of a number of different capacitive touch sensing interfaces, including commercially available capacitive touch sensing interfaces such as the Cypress CapSense™ MBR 3116 Series. In some embodiments the portable communication device 10 includes multiple displays 26 and/or multiple capacitive touch sensing interfaces 30.

With reference to FIG. 1 and FIGS. 4 through 6, the display 26 uses light elements (for example light-emitting diodes (LEDs), organic light-emitting diodes (OLEDs), thin-film transistors (TFTs), or other lighting elements) to light up at least one of a text, a symbol, or a graphic on the display 26. When the text, symbol, and/or graphic is lit up, the text, symbol, and/or graphic is visible through the translucent housing 14 (for example the front housing portion 18).

With reference to FIG. 2, the capacitive touch sensing interface 30 includes a capacitive touch backlight assembly 38. The capacitive touch backlight assembly 38 uses light elements (for example light-emitting diodes (LEDs), organic light-emitting diodes (OLEDs), thin-film transistors (TFTs), or other lighting elements) to light up at least one of a control symbol, a control text, or a control graphic on the capacitive touch sensing interface 30. When the control symbol, control text, and/or control graphic is lit up, the control text, control symbol, and/or control graphic is visible through the translucent housing 14 (for example through the front housing portion 18) thereby providing the user with a visible set of controls associated with the visible display.

With reference to FIG. 1, the portable communication device 10 further includes at least one activation button. In the illustrated embodiment, the portable communication device 10 includes a plurality of activation buttons in the form of a power button 42, a toggle button 46, a first programmable button 50, a press-to-talk button 54, a volume control button 58, and a second programmable button 62. Each of the illustrated activation buttons is disposed along either a top region 66 or a side region 70 of the portable communication device 10 (for example, along an interface between the front housing portion 18 and the back housing portion 22). In other constructions different numbers or types of activation buttons are provided, as well as different locations for the activation buttons than that illustrated.

With reference to FIG. 2, the portable communication device 10 further includes an electronic processor 74 (illustrated schematically). The electronic processor 74 is electrically coupled to the display 26, the capacitive touch sensing interface 30, and to each of the activation buttons 42, 46, 50, 54, 58, and 62. In some embodiments, the electronic processor 74 is mounted to or otherwise forms part of the printed circuit board 34. The electronic processor 74 may be any of a number of different electronic processors, including commercially available processors.

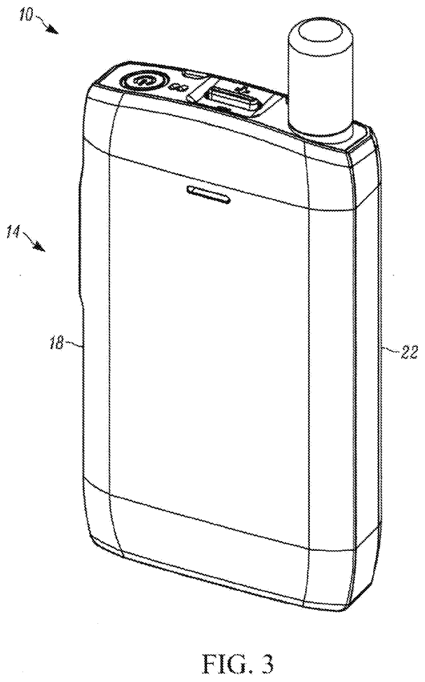

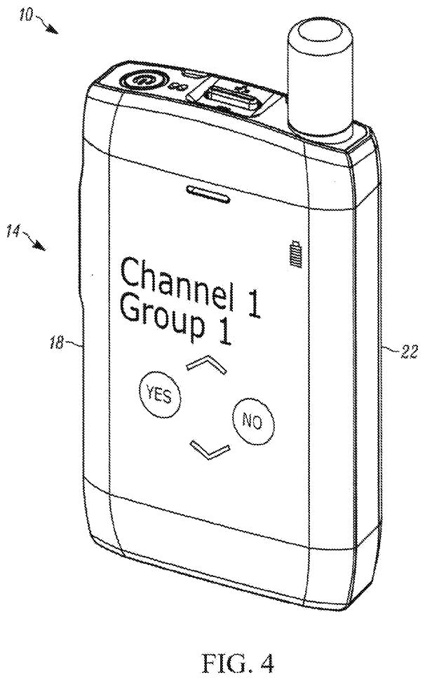

The electronic processor 74 is configured to operate in either in a non-active mode or an active mode. For example, and with reference to FIG. 3, in the non-active mode, lighting of the display 26 and the capacitive touch sensing interface 30 is deactivated, and the front housing portion 18 appears opaque, similar to the back housing portion 22. In the non-active mode, the display 26 and the capacitive touch sensing interface 30 are thus hidden. With reference to FIG. 4, in the active mode the electronic processor 74 is configured to generate light and light up the display 26 and the capacitive touch sensing interface 30, such that at least one symbol, text, or graphic is visible through the translucent housing 14 on the display 26 (for example a text that reads “Channel 1” and “Group 1” as illustrated in FIG. 4) and at least one control symbol, control text, or control graphic is visible through the translucent housing 14 on the capacitive touch sensing interface 30 (for example a set of “up” and “down” arrows and text that reads “YES” and “NO” as illustrated in FIG. 4).

With reference to FIG. 1, in the illustrated embodiment the electronic processor 74 is configured to switch from the non-active mode to the active mode when any one of the activation buttons 42, 46, 50, 54, 58, 62 is pressed. Thus, to light up an initial set of text, symbols, and/or graphics the display 26 and to light up an initial set of control text, control symbols, and/or control graphics on the capacitive touch sensing interface 30, a user may simply press any of the activation buttons 42, 46, 50, 54, 58, 62. In some embodiments, the electronic processor 74 is also or alternatively configured to switch from the non-active mode to the active mode when a push-to-talk call is received by the portable communication device 10.

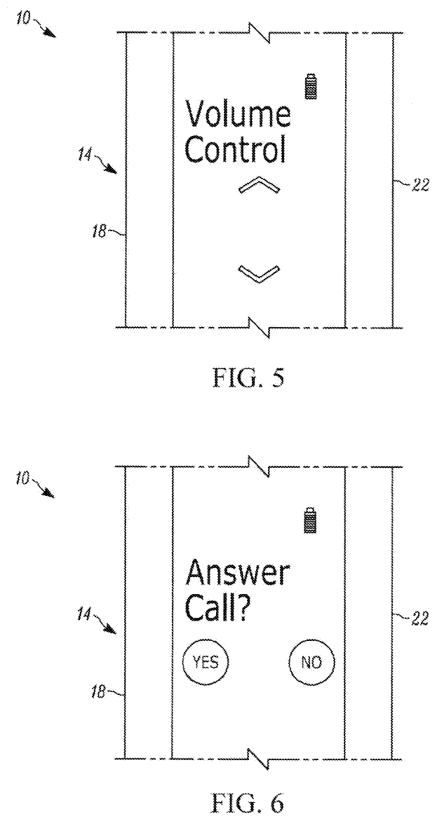

With reference to FIG. 1 and FIGS. 4 through 6, the active mode includes different settings. In each setting, a different set of text, symbols, and/or graphics are shown on the display 26, and a different set of control text, control symbols, and/or control graphics are shown on the capacitive touch sensing interface 30. In use, a user may wish to switch between the different settings in the active mode. For example, as illustrated in FIG. 5, the display 26 shows a text of “Volume CONTROL” and the capacitive touch sensing interface 30 shows control symbols in the form of an “up” arrow and a “down” arrow. In this setting, a user may press on the “up” control symbol to cause the volume on the portable communication device 10 to increase, or may press on the “down” arrow to cause the volume on the portable communication device 10 to decrease. The capacitive touch sensing interface 30 feels the contact of a user's finger on the translucent housing 14. Thus, by simply contacting the translucent housing 14 where the “up” arrow is illuminated, the electronic processor 74 recognizes the touch, and communicates with a speaker 78 (FIG. 2) to increase the volume.

When the user desires to control a different function of the portable communication device 10, the user may press the toggle button 46. When the toggle button 46 is pressed, a different set of text, symbols, and/or graphics are shown on the display 26, and a different set of control text, control symbols, and/or control graphics are shown on the capacitive touch sensing interface 30. For each setting, only the control text, control symbols, and/or control graphics needed are shown on the capacitive touch sensing interface 30. The control text, control symbols, and/or control graphics that are not needed are dimmed and are not visible. For example, with reference to FIG. 5, only the “up” arrow and the “down” arrow are needed for a volume control. Thus, the “YES” and “NO” control text illustrated in FIG. 6 are dimmed. Similarly, in FIG. 6, only the “YES” and “NO” control text are needed. Thus, the “up” arrow and the “down” arrow illustrated in FIG. 5 are dimmed.

With reference to FIG. 6, in some embodiments the display 26 shows a text of “Answer Call?” and the capacitive touch sensing interface 30 shows control text in the form of “YES” and “NO.” This setting may be activated by the electronic processor 74 solely based on an incoming call, as opposed to pressing of the toggle button 46. In some embodiments, other settings may be activated not by pressing of the toggle button 46, but rather by pressing of the power button 42, the first programmable button 50, the press-to-talk button 54, the volume control button 58, or the second programmable button 62. Additionally, in some embodiments, touching the control text, control symbols, and/or control graphics on the capacitive touch sensing interface 30 with a user's finger may itself cause a setting to change, and for a different set of control text, control symbols, and/or control graphics to appear on the capacitive touch sensing interface 30 and/or for a different set of text, symbols, and/or graphics to appear on the display 26. Furthermore, while only a few different types of settings are illustrated in FIGS. 1 through 6, in some embodiments different settings are included, including settings that allow the user to turn off the portable communication device 10, adjust a brightness of the display 26, and perform other functions.

With reference to FIG. 2, the portable communication device 10, in some embodiments, further includes at least one haptic element that provides a tactile feedback to the user when the user has switched settings and/or contacted a control text, control symbol, and/or control graphic on the capacitive touch sensing interface 30. In the illustrated embodiment, the haptic element is a vibrator 82 positioned under the translucent housing 14. The vibrator 82 includes its own motor and is electrically coupled to the electronic processor 74. When a user presses one of the activation buttons (for example the toggle button 46), the electronic processor 74 activates the vibrator 82 to vibrate, thereby providing the user with feedback letting the user know that a setting has been switched, and that a different set of control text, control symbols, and/or control graphics now appears on the capacitive touch sensing interface 30 and/or that a different set of text, symbols, and/or graphics now appears on the display 26. In some embodiments, when a user contacts (for example with a finger) a control text, control symbol, and/or control graphic on the capacitive touch sensing interface 30, the electronic processor 74 causes the vibrator 82 to vibrate, thereby providing the user with feedback. In some embodiments, rather than causing the vibrator 82 to vibrate, the electronic processor 74 communicates with the speaker 78 to activate the speaker 78 to emit a sound or sounds (for example beeping sounds) to provide the user with feedback. In some embodiments, the electronic processor 74 communicates with both the speaker 78 and the vibrator 82 to provide the user with feedback. Other embodiments include use of different haptic elements to provide feedback than that illustrated.

With reference to FIG. 2, the portable communication device 10 further includes a proximity sensor 86. The proximity sensor 86 is positioned under the translucent housing 14, and is electrically coupled to the electronic processor 74. The proximity sensor 86 senses whether the portable communication device 10 is within a predetermined distance (for example one inch, three inches, six inches, or other another distance) of an object. For example, in the illustrated embodiment the proximity sensor is positioned adjacent an earpiece 90 of the portable communication device 10, so that the proximity sensor 86 detects when the earpiece 90 is too close to a user's ear. The proximity sensor 86 may for example be an infrared sensor, inductive sensor, capacitive sensor, photoelectric, ultrasonic sensor, or any other type of proximity sensor. When the proximity sensor 86 senses, and the electronic processor 74 determines, that the portable communication device 10 is within the predetermined distance, the electronic processor 74 is configured to switch to the non-active mode and cause dimming of the control text, control symbols, and/or control graphics appearing on the capacitive touch sensing interface 30 and/or the text, symbols, and/or graphics appearing on the display 26. This reduces the likelihood, for example, of the user placing the portable communication device 10, and more specifically the earpiece 90 of the portable communication device 10 (FIG. 2), too close to the user's ear and accidentally pressing the capacitive touch sensing interface 30 to the user's ear or body, thus switching settings, turning the portable communication device 10 off, causing the portable communication device 10 to perform an undesired function, or otherwise causing false activation.

With reference to FIG. 2, in the illustrated embodiment the portable communication device 10 further includes an antenna 94 and a power source 98 in the form of a battery cell positioned under the translucent housing 14. In some embodiments the power source 98 is rechargeable through a device power connector (not shown). The antenna 94 and the power source 98 are both electrically coupled to the electronic processor 74. Other embodiments include different types of antennas and power sources than that illustrated, as well as different locations for the antenna 94 and the power source 98 than that illustrated.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. A portable communication device comprising:
a translucent housing;
a display positioned under the translucent housing;
a capacitive touch sensing interface positioned under the translucent housing and adjacent the display;
an activation button; and
an electronic processor electrically coupled to the display, the capacitive touch sensing interface, and the activation button.

2. The portable communication device of claim 1, wherein the electronic processor is configured to operate in at least one of a group consisting of non-active mode and an active mode, wherein in the non-active mode, lighting of the display and the capacitive touch sensing interface is deactivated, and wherein in the active mode, the display and the capacitive touch sensing interface generate light.

3. The portable communication device of claim 2, wherein the electronic processor is configured to switch to the active mode when the activation button is pressed.

4. The portable communication device of claim 2, wherein when the electronic processor is in the active mode, the electronic processor is configured to generate at least one of a text, a symbol, or a graphic on the display.

5. The portable communication device of claim 2, wherein when the electronic processor is in the active mode, the electronic processor is configured to generate at least one of a control symbol, a control text, or a control graphic on the capacitive touch sensing interface.

6. The portable communication device of claim 5, wherein the capacitive touch sensing interface includes a backlight assembly that lights up the at least one of the control symbol, the control text, or the control graphic.

7. The portable communication device of claim 1, wherein the activation button is a toggle button, and wherein the electronic processor is configured to change at least one of a text, a symbol, or a graphic on the display based on activation of the toggle button.

8. The portable communication device of claim 1, wherein the electronic processor is configured to light up a control symbol, control text, or control graphic on the capacitive touch sensing interface, and wherein once the activation button has been pressed, the electronic processor is configured to cause dimming of the one control symbol, control text, or control graphic and to light up a different control symbol, control text, or control graphic on the capacitive touch sensing interface.

9. The portable communication device of claim 1, wherein the portable communication device includes a toggle button, a power button, a programmable button, a volume control button, and a press-to-talk button.

10. The portable communication device of claim 9, wherein the electronic processor is configured to operate in at least one of a group consisting of non-active mode and an active mode, and wherein any of the toggle button, the power button, the programmable button, the volume control button, and the press-to-talk button may be pressed to cause the electronic processor to operate in the active mode.

11. The portable communication device of claim 1, wherein the translucent housing includes a front housing portion and a back housing portion that are coupled together, and wherein only the front housing portion is translucent.

12. The portable communication device of claim 1, further comprising a vibrator motor positioned under the translucent housing and coupled to the electronic processor, wherein the electronic processor is configured to activate the vibrator motor when the activation button is pressed.

13. The portable communication device of claim 1, further comprising a speaker positioned under the translucent housing and coupled to the electronic processor, wherein the electronic processor is configured to activate the speaker when the activation button is pressed.

14. The portable communication device of claim 1, further comprising a proximity sensor positioned under the translucent housing and coupled to the electronic processor, wherein the proximity sensor is configured to sense a distance between the device and an object.

15. The portable communication device of claim 14, wherein the electronic processor is configured to operate in a at least one of a group consisting of a non-active mode and an active mode, wherein in the non-active mode, lighting of the display and the capacitive touch sensing interface is deactivated, and wherein in the active mode, the display and the capacitive touch sensing interface generate light, and wherein the electronic processor is configured to switch to the non-active mode if the electronic processor determines that the portable communication device is within a predetermined distance from the other object based on information from the proximity sensor.

16. The portable communication device of claim 1, wherein the display includes at least one of a group consisting of a light emitting diode, an organic light-emitting diode, and a thin-film transistor.

17. The portable communication device of claim 1, wherein the capacitive touch sensing interface includes at least one of a group consisting of a light emitting diode, an organic light-emitting diode, and a thin-film transistor.

18. A portable communication device comprising:
a translucent housing;
a capacitive touch sensing interface positioned under the translucent housing, wherein the capacitive touch sensing interface includes a lighting assembly with organic light-emitting diodes that generate at least one of a control symbol, a control text, or a control graphic on the capacitive touch sensing interface;
an activation button coupled to the translucent housing;
a proximity sensor positioned under the translucent housing; and
an electronic processor electrically coupled to the capacitive touch sensing interface, the activation button, and the proximity sensor;
wherein the portable communication device includes a non-active mode and an active mode, wherein in the non-active mode, the capacitive touch sensing interface is not visible through the translucent housing, and wherein in the active mode, the capacitive touch sensing interface is visible through the translucent housing;
wherein in the active mode, the electronic processor is configured to light up one control symbol, control text, or control graphic with the organic light-emitting diodes, and wherein once the activation button has been pressed, the electronic processor is configured to cause dimming of the one control symbol, control text, or control graphic and to light up a different control symbol, control text, or control graphic.

19. The portable communication device of claim 18, further comprising a vibrator motor positioned under the housing and coupled to the electronic processor, wherein the electronic processor is configured to activate the vibrator motor when the activation button is pressed.

20. The portable communication device of claim 18, further comprising a speaker positioned under the housing and coupled to the electronic processor, wherein the electronic processor is configured to activate the speaker when the activation button is pressed.
